(19) United States
(12) Patent Application Publication
(10) Pub. No.: US 2003/0047205 A1
(43) Pub. Date: Mar. 13, 2003

(54) Thermoelectric device four for producing an electric current

(76) Inventor: Beecher J. Holland, Kingsport, TN (US)

Correspondence Address: Beecher J. Holland, 600 Morison Ave, Kingsport, TN, 37660, US

(21) Appl. No.: 09/949,524

(22) Filed: Sep. 10, 2001

(51) Int. Cl. H01L 35/30

(52) U.S. Cl. 136/205

(57) ABSTRACT

The present invention is an electric-current-producing thermoelectric device of a variety described by U.S. Pat. No. 6,225,549B1 or U.S. Pat. No. 6,245,986B1 or application Ser. No. 09,805,967 wherein an appendage connects to the cathode of the thermoelectric cell system, the appendage being a thermally-induced-electron replenisher for the cell system.

### BACKGROUND OF THE INVENTION

1. Field of the Invention

The present invention pertains to an electrical-current-producing thermoelectric device.

2. Description of the Related Art

The three most nearly related prior art devices appear to be U.S. Pat. No. 6,225,549B1 dated May 1, 2001, U.S. Pat. No. 6,245,986B1 dated Jun. 12, 2001 and application Ser. No. 09/805,967 filed Mar. 9, 2001, all three by the present author. It has been noted on several occasions that at least some of the above devices, thermoelectric cells, apparently have a tendency to operate for some time at a higher level of output, and then over a short period fall to a much lower output, 2:15 A.M. of Aug. 22, 2001, in some cases subsequently returning to an intermediate output and in some apparently not. The observation is possibly and probably typical of all cells of the preceding three references. Avoiding sharp drop in output appears possibly feasible by means currently being tested.

### SUMMARY OF THE INVENTION

It appears that sharp drop in output from the referenced variety of thermoelectric cells may be the result of unusually greater boil-off of electrons from a circuit external to a cell system at the expense of the cell system than would be normal for the cell system laying dormant, that is without a closed circuit connected to the cell system. Such sharp drop in output appears correctable and probably avoidable by unusual means currently being-tested, starting 7:56 A.M. of Aug. 22, 2001, that is an appendage electrically connected to the cathode of a cell system of one or more cells, the appendage being a thermally-induced electron-emission-means-electron-replenisher, for the cell system, which communicates with at least one of its ambient conditions in regard to receiving electrons for its own replenishment.

### BRIEF DESCRIPTION OF THE DRAWING

The single embodiment of the present invention will herein be described by drawing for clarification of design and function of the embodiment.

FIG. 1 is a schematic of a cell system comprised of multiple thermoelectric cells of a type described by application Ser. No. 09/805,967 filed Mar. 9, 2001, that is multiple single-or-multiple-cell systems in parallel accomplished by a copy of a drawn image on a section of paper.

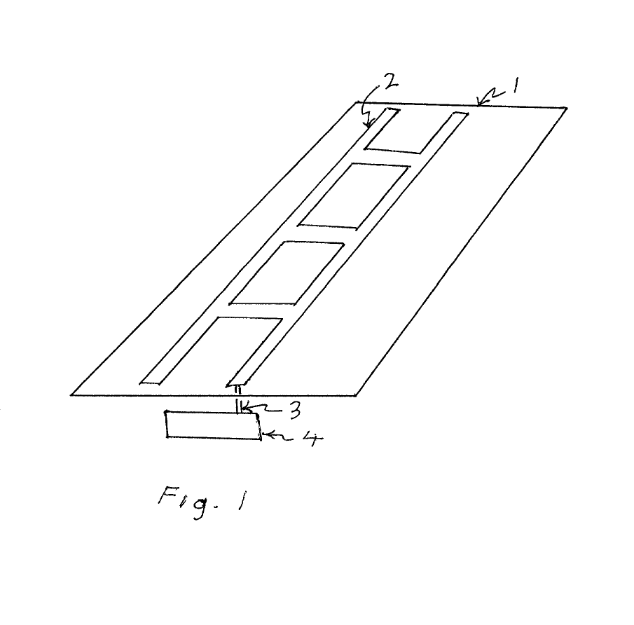

Item 1 of FIG. 1 is a section of paper, structural vehicle for the cell system Item 2. Item 2 is a machine copy of a drawn cell system wherein the shorter bars are each a separate cell system acting in parallel with the other shorter bars. The two longer bars of Item 2 constitute an output anode line and a return cathode line wherein either longer bar can serve as anode or cathode line so long as anode and cathode attachments are at opposite ends of Item 2 and on opposite sides of Item 2. Item 3 is an electrical lead means from the part of Item 2 chosen as cathode to Item 4 electron-emission-means-electron-replenisher.

### DESCRIPTION OF THE PREFERRED EMBODIMENT

When the cell system Item 2 absorbs heat from its surroundings, and the lower-right extremity of the cell system is connected by circuitry to the upper-left extremity of the cell system in which circuitry electrical load is nearer the upper-left extremity in terms of resistance and induces greater electron density in the upper-left extremity, current apparently flows from the upper-left to the lower-right. Electrons “boiled off” in the electrical load appear to be replaced by migration from Item 4 electron replenisher through electrical lead Item 3 to the lower-right extremity of Item 2. It is expected that Item 4 electron replenisher is itself replenished with electrons from atmospheric air to which it is exposed.

I claim:

1. An electric-current-producing thermoelectric device comprised of a cell system comprising one or more cells of a variety described by U.S. Pat. No. 6,225,549B1 dated May 1, 2001 or U.S. Pat. No. 6,245,986B1 dated Jun. 12, 2001 or application Ser. No. 09/805,967 filed Mar. 9, 2001, wherein
an appendage connects electrically to the cathode of said cell system, wherein
said appendage being a thermally-induced electron-emission-means communicating with at least one of its ambient conditions.
